(19) United States
(12) Patent Application Publication
(10) Pub. No.: US 2020/0118910 A1
(43) Pub. Date: Apr. 16, 2020

(54) CHIP STRUCTURE

(71) Applicant: ASELSAN ELEKTRONIK SANAYI VE TICARET ANONIM SIRKETI, Ankara (TR)

(72) Inventors: Ahmet AKTUG, Ankara (TR); Murat Erdal DAGDELEN, Ankara (TR)

(73) Assignee: ASELSAN ELEKTRONIK SANAYI VE TICARET ANONIM SIRKETI, Ankara (TR)

(21) Appl. No.: 16/626,890

(22) PCT Filed: Jan. 30, 2018
(86) PCT No.: PCT/TR2018/050032

§ 371 Date: Dec. 27, 2019

(51) Int. Cl. H01L 23/48; H01L 23/66; H01L 23/528; H01L 23/532; H01L 29/20; G01S 7/03; G01S 13/02

(52) U.S. Cl. CPC H01L 23/481; H01L 23/66; H01L 23/528; H01L 23/53228; G01S 2007/028; G01S 7/032; G01S 13/02; H01L 2223/6616; H01L 29/20

(57) ABSTRACT

A chip structure, suitable to be used in radar applications includes, at least one gallium based first layer to perform RF applications; at least one gallium based second layer, placed on the first layer, to perform digital applications; at least two copper based pillars located between the first layer and the second layer, which provide electrical connection between the first layer and second layer and which ensure that there is a safe distance between the first layer and second layer.

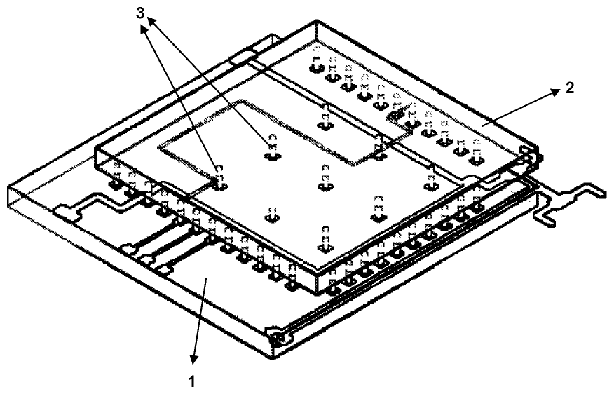

### CROSS REFERENCE TO THE RELATED APPLICATIONS

This application is the national phase entry of International Application No. PCT/TR2018/050032, filed on Jan. 30, 2018, the entire contents of which are incorporated herein by reference.

### TECHNICAL FIELD

The present invention is related to a chip structure especially suitable to be used in phased array radar applications.

### BACKGROUND

Phased array radars consists of multiple receive and/or transmit modules and antennas which have to be separated by certain distance imposed by wavelength. Depending on frequency band of operation, distance between modules has to be very small. In phased array radar applications, different tasks (such as sending signals, receiving signals, processing signals etc.) are performed almost simultaneously. Due to both limited available space for each microwave module and high number of task assigned, chips used in modules are required to be small in size. Moreover, brittle nature of chips brings maximum chip size limitations for handling.

Most of the silicone based semiconductor technologies are compliant with analogue, digital, and RF circuits, therefore it is possible to form a silicone based compact multi-channel chip having analogue, digital, and RF circuits simultaneously. However, some critical RF performance of the silicon based technologies are limited (noise figure, output power etc.) compared other semiconductor technologies (such as gallium arsenide). Although, GaAs based technologies have better RF performance, it has lower level of integrity than silicone based technologies which increases the chip dimensions to unacceptable levels.

### SUMMARY

In the present invention, a chip structure, suitable to be used in phased array radar applications is provided. Said chip structure comprises, at least one gallium based first layer to perform RF applications; at least one gallium based second layer, placed on said first layer, to perform digital applications; at least two copper based pillars located between the first layer and the second layer, which provide electrical connection between the first layer and second layer and which ensure that there is a safe distance between the first layer and second layer to prevent any undesired RF couplings.

In the present application, the chip structure has plurality of layers for performing different applications (namely RF applications and digital applications). RF applications are performed with high performance in first layer and digital applications are performed in second layer. Therefore, with the chip structure of the present application, both RF applications and digital applications are performed in a much smaller footprint.

An object of the invention is to provide a chip structure performing both digital and RF applications.
The other object of the invention is to provide a compact chip structure having high performance on digital and RF applications.
Another object of the invention is to provide a chip structure suitable to be used in phased array radar applications.

### BRIEF DESCRIPTION OF THE DRAWINGS

FIGURE shows a perspective view of the chip structure of the present application.

All the parts illustrated in the drawing are individually assigned a reference numeral and the corresponding terms of these numbers are listed as follows:
First layer (1)
Second layer (2)
Pillar (3)

### DETAILED DESCRIPTION OF THE EMBODIMENTS

In the radar applications, digital and RF circuits are needed to be used together. In order to perform multi-channel digital and RF processes on a single chip, silicone based structures are commonly used. However, since RF performance of the silicone based structures are limited, overall performances of said single chip structures are limited. Therefore, with the present invention, a chip structure performing both digital and RF applications is provided.

A perspective view of the chip structure of the present invention is given in FIGURE. Said chip structure comprises at least one gallium based (such as gallium arsenide—GaAs, gallium nitride—GaN etc.) first layer (1) to perform RF applications; at least one gallium based (such as gallium arsenide—GaAs, gallium nitride—GaN etc.) second layer (2), placed on said first layer (1), to perform digital applications; at least two copper based pillars (3) located between the first layer (1) and the second layer (2), which provide electrical connection between the first layer (1) and second layer (2) and which ensure that there is a safe distance between the first layer (1) and second layer (2).

In an exemplary embodiment of the present invention, gallium arsenide based first layer (1) is connected to a control unit for sending/receiving signals/commands. Signals/commands received by the first layer (1) are sent to the second layer (2) through copper based pillars (3). Therefore, a safe electrical connection between the first layer (1) and second layer (2) is provided. Moreover, said pillars (3) ensure that there is a safe distance between the first layer (1) and second layer (2). In detail, during the design of the first layer (1), it is assumed that there is only air above the first layer (1). Therefore, in order to perform desired RF functions, parameters of the first layer (1) determined accordingly. However, when a second layer (2) is placed on top of the first layer (1), RF functions of the first layer (1) may be effected. In order to avoid such situation, there must be a safe distance between the first layer (1) and second layer (2). Since said pillars (3) ensures said safe distance, according to the present invention, RF performance of the first layer (1) is not effected by the second layer (2).

In a preferred embodiment of the present application, length of each said pillars (3) is between 30-50 um (preferably 40 um). Studies show that, when the distance between the first layer (1) and second layer (2) is kept higher than 50 um, RF performance of first layer (1) is minimally affected by second layer (2).

In another preferred embodiment of the present application, components of the second layer (2) face the first layer (1). Thanks to said structure, connection between the first layer (1) and second layer (2) is provided more easily and reliably.

In another preferred embodiment of the present application, first layer (1) is in the form of a four channeled chip. Similarly, second layer (2) is preferably in the form of a four channeled chip. Therefore, in this embodiment, chip structure has four channels. Thanks to the multilayer structure of the chip structure of the present application, four channel chip is provided with small size.

In the present application, the chip structure has plurality of layers for performing different applications (namely RF applications and digital applications). RF applications are performed with high performance in first layer (1) and digital applications are performed in second layer (2). Therefore, with the chip structure of the present application, both RF applications and digital applications are performed in a much smaller footprint.

What is claimed is:

1. A chip structure, suitable to be used in radar applications, comprising:
at least one gallium based first layer to perform RF applications;
at least one gallium based second layer, placed on the at least one gallium based first layer, to perform digital applications;
a plurality of copper based pillars located between the at least one gallium based first layer and the at least one gallium based second layer, the plurality of copper based pillars provide an electrical connection between the at least one gallium based gallium based first layer and the at least one gallium based gallium based second layer and the plurality of copper based pillars provide a gap between the at least one gallium based first layer and the at least one gallium based second layer.

2. The chip structure according to claim 1, wherein, a length of the plurality of copper based pillars is between 30-50 um.

3. The chip structure according to claim 1, wherein, a length of the plurality of copper based pillars is 40 um.

4. The chip structure according to claim 1, wherein, a plurality of components of the at least one gallium based second layer face the at least one gallium based first layer.

5. The chip structure according to claim 1, wherein, the at least one gallium based first layer is in the form of a four channeled chip.

6. The chip structure according to claim 1, wherein, the at least one gallium based second layer is in the form of a four channel chip.

7. The chip structure according to claim 5, wherein, the at least one gallium based second layer is in the form of a four channeled channel chip.
